(19) United States
(12) Patent Application Publication
(10) Pub. No.: US 2025/0224556 A1
(43) Pub. Date: Jul. 10, 2025

(54) PACKAGE ASSEMBLY AND METHOD OF FORMING THE SAME

(71) Applicant: Taiwan Semiconductor Manufacturing Company, Ltd., Hsinchu (TW)

(72) Inventors: Chen-Hua Yu, Hsinchu City (TW); Tung-Liang Shao, Hsinchu (TW); Yu-Sheng Huang, Changhua County (TW)

(73) Assignee: Taiwan Semiconductor Manufacturing Company, Ltd., Hsinchu (TW)

(21) Appl. No.: 18/403,746

(22) Filed: Jan. 4, 2024

(51) Int. Cl. G02B 6/12; G02B 6/124; H01L 23/00; H01L 23/498; H01L 25/065

(52) U.S. Cl. CPC G02B 6/12004; G02B 6/124; H01L 23/49816; H01L 23/49822; H01L 24/08; H01L 24/16; H01L 25/0652; H01L 2224/08146; H01L 2224/08165; H01L 2224/16137; H01L 2224/16146; H01L 2924/1431; H01L 2924/1435; H01L 2924/15311; H01L 2924/182

(57) ABSTRACT

A method of forming a package assembly includes the following operations. At least one integrated circuit structure is bonded to an interposer structure. A photonic structure is bonded to the interposer structure aside the at least one integrated circuit structure. A glass substrate is assembled to a fiber array unit. The glass substrate with the fiber array unit is bonded to the photonic structure. A laser writing process is performed to the glass substrate, so as to form a laser written waveguide structure inside the glass substrate, wherein the laser written waveguide structure is optically coupled to the fiber array unit and the photonic structure.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area. Although the existing integrated circuit packages or package assemblies have been generally adequate for their intended purposes, they have not been entirely satisfactory in all respects.

### BRIEF DESCRIPTION OF THE DRAWINGS

FIG. 1 to FIG. 5 are schematic cross-sectional views of a method of forming a package assembly in accordance with some embodiments.

FIG. 6, FIG. 7 and FIG. 9 are schematic local perspective views of package assemblies in accordance with some embodiments.

FIG. 8 to FIG. 10 are schematic local cross-sectional views of package assemblies in accordance with some embodiments.

FIG. 11 to FIG. 16 are schematic cross-sectional views of a method of forming a package assembly in accordance with some embodiments.

FIG. 17 to FIG. 18 are schematic local cross-sectional views of package assemblies in accordance with some embodiments.

FIG. 19 illustrates a method of forming a package assembly in accordance with some embodiments.

FIG. 20 illustrates a method of forming a package assembly in accordance with some embodiments.

### DETAILED DESCRIPTION

The following disclosure provides many different embodiments, or examples, for implementing different features of the provided subject matter. Specific examples of components and arrangements are described below for the purposes of conveying the disclosure in a simplified manner. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the same or similar reference numerals and/or letters may be used to refer to the same or similar element in the various examples of the disclosure. The repeated use of the reference numerals is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein to facilitate the description of one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments described herein disclose package assemblies such as photonic-electric integrated circuit (IC) packages. With the three-dimensional (3D) laser written waveguide structure of the disclosure, the misalignment issue between a fiber array unit (FAU) and a photonic structure can be easily resolved, and the coupling tolerance between the FAU and the photonic structure can be greatly improved. With optical interconnection provided by the photonic structure, higher communication performance and more compact packaging can be easily achieved.

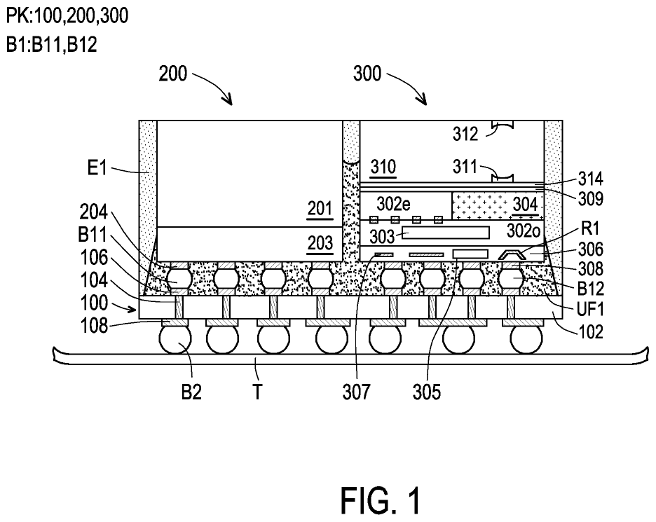

FIG. 1 to FIG. 5 are schematic cross-sectional views of a method of forming a package assembly in accordance with some embodiments. It is understood that the disclosure is not limited by the method described below. Additional operations can be provided before, during, and/or after the method and some of the operations described below can be replaced or eliminated, for additional embodiments of the methods. Although FIG. 1 to FIG. 5 are described in relation to a method, it is appreciated that the structures disclosed in FIG. 1 to FIG. 5 are not limited to such a method, but instead may stand alone as structures independent of the method.

Referring to FIG. 1, at least one semiconductor package PK is attached to a wafer tape T. In some embodiments, the semiconductor package PK includes an interposer structure 100, an integrated circuit structure 200 and an photonic structure 300 bonded to the interposer structure 100. The integrated circuit structure 200 may include a system device, and the photonic structure 300 may include a photonic device, which will be described in details below. However, the disclosure is not limited thereto. In other embodiments, the semiconductor package PK further includes an additional integrated circuit structure bonded to the interposer structure 100 and aside the integrated circuit structure 200. The additional integrated circuit structure may include a memory device such as a dynamic random-access memory (DRAM), a synchronous dynamic random-access memory (SDRAM), a die stack such as a high bandwidth memory (HBM) cube, or the like.

In some embodiments, the interposer structure 100 includes a substrate 102, and through substrate vias 104 penetrating through the substrate 102. The substrate 102 may include elementary semiconductor such as silicon, germanium and/or a compound semiconductor such as silicon germanium, silicon carbide, gallium arsenic, indium arsenide, gallium nitride or indium phosphide. The through substrate vias 104 may include metal such as copper and insulated from the substrate 102 by insulating liners. In some embodiments, the interposer structure 100 further includes a conductive structure disposed between the substrate 102 and the integrated circuit structure 200 or the photonic structure 300 and electrically connected to the through substrate vias 104. The conductive structure may include conductive features embedded by dielectric layers.

In some embodiments, the interposer structure 100 further includes metal pads 104 and metal pads 108 at opposite sides and configured to electrically connected to the overlying and underlying electrical components, semiconductor devices or integrated circuit structures, respectively. In some embodiments, bumps B1 and bumps B2 are further formed on and electrically connected to the metal pads 104 and the metal pads 108, respectively. The bumps B1 may be divided into bumps B11 and bumps B12 for different overlying electrical structures. The bumps B1 and the bumps B2 include solder bumps, and/or may include metal pillars (e.g., copper pillars), solder caps formed on metal pillars, and/or the like. The bumps B1 are referred to as “micro bumps” in some examples. The bumps B2 are referred to as “controlled collapse chip connection (C4) bumps” in some examples. The size of the bumps B2 may be different from (e.g., greater than) the size of the bumps B1.

In some embodiments, the interposer structure 100 is an active interposer that contains at least one functional device or integrated circuit device included in the conductive structure or the substrate. Such active interposer is referred to as a “device-containing interposer” in some examples. In some embodiments, the functional device includes an active device, a passive device, or a combination thereof. The functional device includes, for example but not limited to, transistors, capacitors, resistors, diodes, photodiodes, fuse devices and/or other similar components. In other embodiments, the interposer structure 100 is a passive interposer, which is lack of a functional device or integrated circuit device. Such passive interposer is referred to as a “device-free interposer” in some examples.

Still referring to FIG. 1, an integrated circuit structure 200 is bonded to the interposer structure 100. The integrated circuit structure 200 may include a system device such as application-specific integrated circuit (ASIC), a field programmable gate array (FPGA), a central processing unit (CPU) die, a graphics processing unit (GPU) die, a multi-core general purpose processors (xPU) die, an artificial intelligence (AI) engine die, a transceiver (TRX) die, or the like. In some embodiments, the integrated circuit structure 200 (e.g., system device) includes a substrate 201 and a device layer 203. The substrate 201 may include elementary semiconductor such as silicon, germanium and/or a compound semiconductor such as silicon germanium, silicon carbide, gallium arsenic, indium arsenide, gallium nitride or indium phosphide. The substrate 201 may be doped as needed. The device layer 203 may include a transistor such as a fin field effect transistor (FinFET), a nanostructure FET (nano-FET) (e.g., a nanosheet transistor, a nanowire transistor or a gate-all-around transistor), a planar FET, the like, or a combination thereof. The device layer 203 may further include an interconnect structure electrically connected to the transistor.

In some embodiments, the integrated circuit structure 200 (e.g., system device) further includes metal pads 204 configured to electrically connected to the underlying electrical component, semiconductor device or integrated circuit structure. Specifically, the integrated circuit structure 200 (e.g., system device) is bonded to the interposer structure 100 through the metal pads 204, bumps B11 and the metal pads 104. The bumps B11 may be formed over the metal pads 204, the metal pads 104 or both.

Still referring to FIG. 1, a photonic structure 300 is bonded to the interposer structure 100. In some embodiments, the photonic structure 300 includes, from bottom to top, a photonic die 3020, an electric die 302e and a support die 310. The photonic structure 300 may be referred to as a silicon photonic (SiPh) structure in some examples.

In some embodiments, the photonic die 3020 includes a photonic integrated circuit (PIC) 303. The PIC 303 includes an optical waveguide (such as silicon (Si) waveguide), a modulator, a detector, a grating coupler, a filter, other optical components, or a combination thereof. In some embodiments, the photonic die 3020 further includes at least one reflector R1, at least one optical component 305, and conducive features 307 embedded in at least one dielectric layer 306. The reflector R1 is configured to reflect a light beam to the desired direction or the desired optical component. The optical component 305 is optically coupled to the PIC 303. In some embodiments, the optical component 305 includes an edge coupler (EC) and an optical waveguide, and the edge coupler is between the reflector R1 and the optical waveguide. The optical waveguide included in the optical component 305 includes a silicon nitride (SiN) waveguide, silicon carbide (SiC) waveguide, silicon carbon nitride (SiCN) waveguide or the like. The material of the optical waveguide in the dielectric layer 306 is different from the material of the optical waveguide inside the PIC 303. The silicon nitride waveguide in the optical component 305 has a lower signal propagation loss than the silicon waveguide in the PIC 303, and is used to transmit the optical signal over a relatively longer distance. The conducive features 307 of the photonic structure 300 are configured to electrically connected to the underlying interposer structure 100. The reflector R1 and the conducive features 307 may include metal (such as copper) and may be formed by electroplating processes or sputtering processes. The dielectric layer 306 may include silicon oxide, silicon nitride, silicon oxynitride, the like, or a combination thereof, and may be formed by deposition processes.

In some embodiments, the method of forming the photonic die 3020 may include: providing a silicon-on-insulator (SOI) substrate, forming a PIC 303 on/in the active side (e.g., front side) of a silicon layer of the SOI substrate, removing an oxide layer and a semiconductor layer of the SOI substrate, and forming at least one optical component 305, at least one reflector R1 and conducive features 307 embedded in at least one dielectric layer 306 on the non-active side (e.g., backside) of the silicon layer.

In some embodiments, the electric die 302e includes an electric integrated circuit (EIC). The PIC of the photonic die 3020 is integrated with the EIC of the electric die 302e, so as to achieve a higher communication performance and a more compact packaging. In some embodiments, the electric die 302e is bonded to the photonic die 3020 through a hybrid bonding including a dielectric-to-dielectric bonding and a metal-to-metal bonding.

In some embodiments, the dimension (e.g., width) of the electric die 302e is less than the dimension (e.g., width) of the photonic die 3020, and an insulating material 304 is provided aside the electric die 302e to fill the space and robust the structure. The insulating material 304 may include a dielectric material, a polymer material or a combination thereof. The dielectric material may include silicon oxide, silicon nitride, silicon oxynitride, the like, or a combination thereof, and may be formed by a deposition process. The polymer material may include polybenzoxazole (PBO), polyimide (PI), benzocyclobutene (BCB), a molding compound (e.g., epoxy) and may be formed by a depositing process or a molding process.

In some embodiments, the support die 310 is a semiconductor die, such as a silicon die. The support die 310 may include elementary semiconductor such as silicon, germanium and/or a compound semiconductor such as silicon germanium, silicon carbide, gallium arsenic, indium arsenide, gallium nitride or indium phosphide.

In some embodiments, the support die 310 includes at least one optical lens 311 and at least one optical lens 312 at opposite sides thereof. The optical lens 311 and the optical lens 312 may be aligned with each other. The optical lens 311 and the optical lens 312 may be embedded in the support die 310 and face each other. The optical lens 311 and the optical lens 312 are configured to condense a light beam in a desired cross section, or focus a light beam in the desired direction. In some embodiments, each of the optical lens 311 and the optical lens 312 may have an optical recessed feature. In some embodiments, each of the optical lens 311 and the optical lens 312 has a substantially vertical sidewall and a convex bottom. The shape of the optical lens 311 may be symmetrical to the shape of the optical lens 312, and may be designed to have the desired curvature for focusing a light beam to the underlying optical component.

In some embodiments, the method of forming each of the optical lens 311 and the optical lens 312 includes performing an etching process or a laser process to formed a recessed feature, and filling the recessed feature with an optical material or transparent material. The optical material having a transmission percentage of about 80-99% (e.g., 85-95% or 88-92%). In some embodiments, the optical material includes an optical liquid silicone rubber, poly(methyl methacrylate) (PMMA), an optical epoxy, the like, or a combination thereof. In some embodiments, the optical material includes a high numerical aperture (NA) material having a NA of about 0.2 to 0.5. In some embodiments, the optical material is formed using dispensing, injecting, and/or spraying process, followed by a planarization process.

In some embodiments, the support die 310 is bonded to the electric die 302e through a fusion bonding such as a dielectric-to-dielectric bonding or a polymer-to-polymer bonding. Specifically, the support die 310 is bonded to the electric die 302e through a dielectric bonding layer 314 and a dielectric bonding layer 309. Each of the dielectric bonding layer 314 and the dielectric bonding layer 309 includes a dielectric layer such as silicon oxide, silicon nitride, silicon oxynitirde, silicon oxycarbide, the like, or a combination thereof. The dielectric layer may be replaced by a polymer layer or an insulating layer as needed.

In some embodiments, the photonic structure 300 (e.g., photonic device) further includes metal pads 308 configured to electrically connected to the underlying electrical component, semiconductor device or integrated circuit structure. Specifically, the photonic structure 300 (e.g., photonic device) is bonded to the interposer structure 100 through the metal pads 308, bumps B12 and the metal pads 104. The bumps B12 may be formed over the metal pads 308, the metal pads 104 or both.

Still referring to FIG. 1, after the integrated circuit structure 200 and the photonic structure 300 are bonded to the interposer structure 100, an underfill layer UF1 is formed to fill the space between the interposer structure 100 and each of the integrated circuit structure 200 and the photonic structure 300, and surrounds the bumps B1 including bumps B11 and B12. In some embodiments, the underfill layer UF1 includes a molding compound such as epoxy, and is formed using dispensing, injecting, and/or spraying process. The underfill layer UF1 between two adjacent structures may have a curve and concave surface. The underfill layer UF1 may be omitted in some examples.

Thereafter, an encapsulation layer E1 is formed over the interposer structure 100 and laterally surrounds the integrated circuit structure 200 and the photonic structure 300. In some embodiments, the encapsulation layer E1 includes a molding compound, a molding underfill, a resin or the like. In some embodiments, the encapsulation layer E1 includes a polymer material such as polybenzoxazole (PBO), polyimide, benzocyclobutene (BCB), the like, or a combination thereof. The encapsulation layer E1 may be formed by a molding process followed by a curing process.

In some embodiments, a wafer dicing process is performed, so as to separate adjacent semiconductor packages PK from each other. Each semiconductor package PK may have substantially straight sidewalls. In some embodiments, the semiconductor package PK includes an interposer structure 100, an integrated circuit structure 200 and an photonic structure 300 bonded to the interposer structure 100, and an encapsulation layer E1 laterally encapsulates sidewalls of the integrated circuit structure 200 and the photonic structure 300.

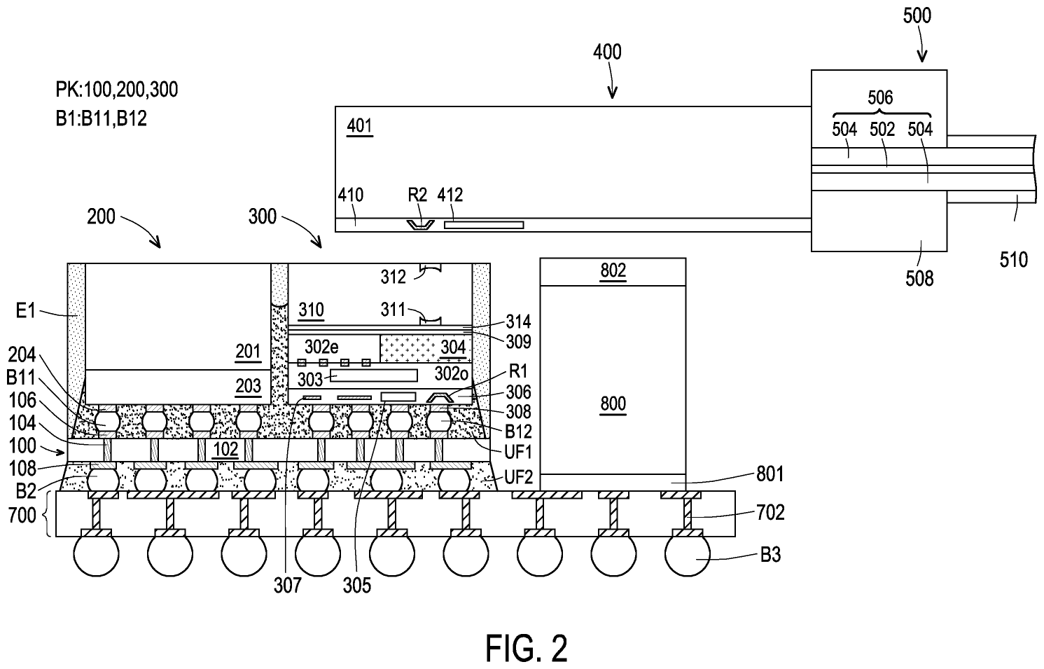

Referring to FIG. 1 and FIG. 2, the wafer tape T is removed, and a board substrate 700 is formed below and electrically connected to the interposer structure 100. In some embodiments, the board substrate 700 is bonded to the interposer structure 100 through the bumps B2.

In some embodiments, the board substrate 700 includes a core layer and two build-up layers on opposite sides of the core layer. In some embodiments, the board substrate 700 includes wiring patterns 702 that penetrate through the core layer and the build-up layers for providing electrical routing between different devices and electric components. The wiring patterns 702 include lines, vias, pads and/or connectors. The board substrate 700 is referred to as a “printed circuit board (PCB)” in some examples. In other embodiments, the core layer of the board substrate 700 may be omitted as needed, and such board substrate 700 is referred to as a “coreless board substrate”.

Thereafter, an underfill layer UF2 is formed to fill the space between the interposer structure 100 and the board substrate 700, and surrounds the bumps B2. In some embodiments, the underfill layer UF2 includes a molding compound such as epoxy, and is formed using dispensing, injecting, and/or spraying process.

In some embodiments, a support structure 800 is provided and bonded to the board substrate 700 aside the photonic structure 300 of the semiconductor package PK. The support structure 800 is configured to support the overlying glass substrate and therefore robust the final structure. In some embodiments, the support structure 800 is a wall structure at a single side of the photonic structure 300, or a ring structure surrounding the photonic structure 300. In such case, the support structure 800 include a heat dissipation material, such as metal. The support structure 800 is attached to the board substrate 700 through an adhesive layer 801. In some embodiments, the support structure 800 has a buffer layer 802 on top thereof. The buffer layer 802 may be an adhesive layer or a thermal interface material (TIM). However, the disclosure is not limited thereto. In other embodiments, the support structure 800 may be a silicon dummy die for eliminating the coefficient thermal expansion (CTE) mismatch and therefore reducing the package warpage issue.

Afterwards, bumps B3 are formed below and electrically connected to the board substrate 700. In some embodiments, bump B3 are electrically to the wiring patterns 702 of the board substrate 700. In some embodiments, the bumps B3 include solder bumps, and/or may include metal pillars (e.g., copper pillars), solder caps formed on metal pillars, and/or the like. The bumps B3 are referred to as “ball grid array (BGA) balls” in some examples. The size of the bumps B3 may be different from (e.g., greater than) the size of the bumps B2.

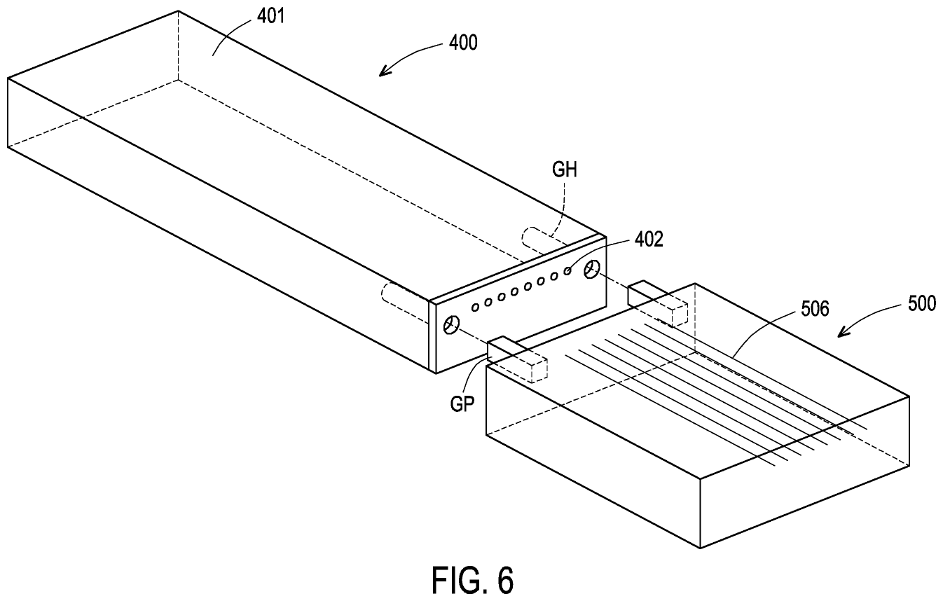

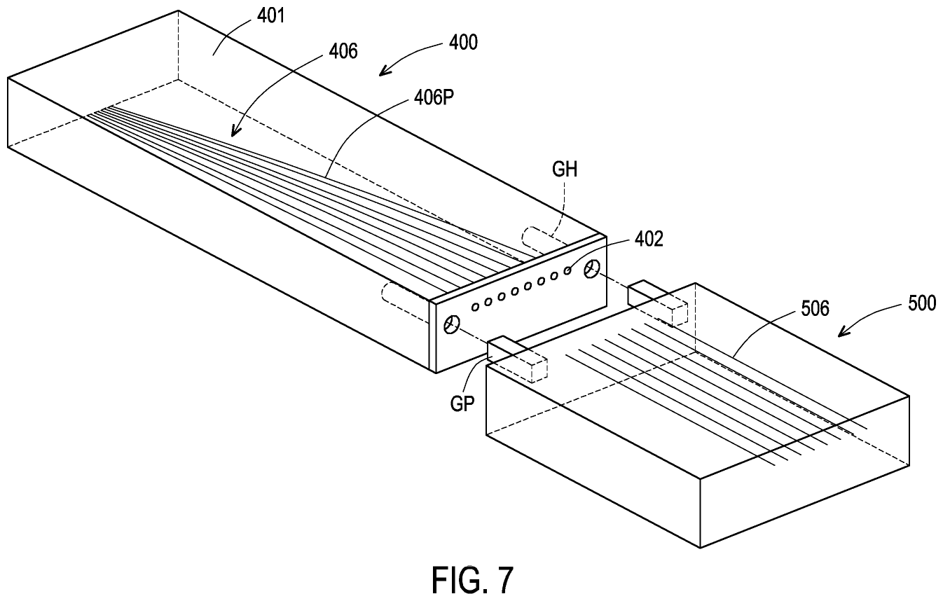

Referring to FIG. 2 and FIG. 6, a glass substrate 400 is assembled to a fiber array unit (FAU) 500. In some embodiments, as shown in FIG. 6, the glass substrate 400 has two guide holes GH, the FAU 500 has two guide pins GH, and the glass substrate 400 is assembled to the FAU 500 with the guide pins GH aligning with and embedded to the guide holes GH. The glass substrate 400 is free of laser written patterns at this stage. In some embodiments, the glass substrate 400 has a width of about 5 mm to 7 mm, a length of about 15 mm to 20 mm, and a height of about 1 mm to 3 mm. Other values and ranges may be applicable upon the customer requirements.

In some embodiments, the glass substrate 400 includes a glass base 401 and has at least one optical coupler 412 and at least one reflector R2 embedded in at least one dielectric layer 410 below the glass base 401. The optical coupler 412 is configured to regulate a light beam emitted from a light source. In some embodiments, the optical coupler 412 is an evanescent coupler (EVC). The reflector R2 is configured to reflect a light beam to the desired direction or the desired optical component. The reflector R2 may include metal (such as copper) and may be formed by an electroplating process or a sputtering process. The dielectric layer 410 may include silicon oxide, silicon nitride, silicon oxynitride, the like, or a combination thereof, and may be formed by deposition processes.

Still referring to FIG. 2 and FIG. 6, the FAU 500 includes optical fibers 506 arranged in an array. In some embodiments, each optical fiber 506 includes a glass core 502 and a glass cladding 504 surrounding the glass core 502. In some embodiments, portions of the optical fibers 506 are embedded in a ferrule 508, and the remaining portions of the optical fibers 506 are embedded in a fiber ribbon 510.

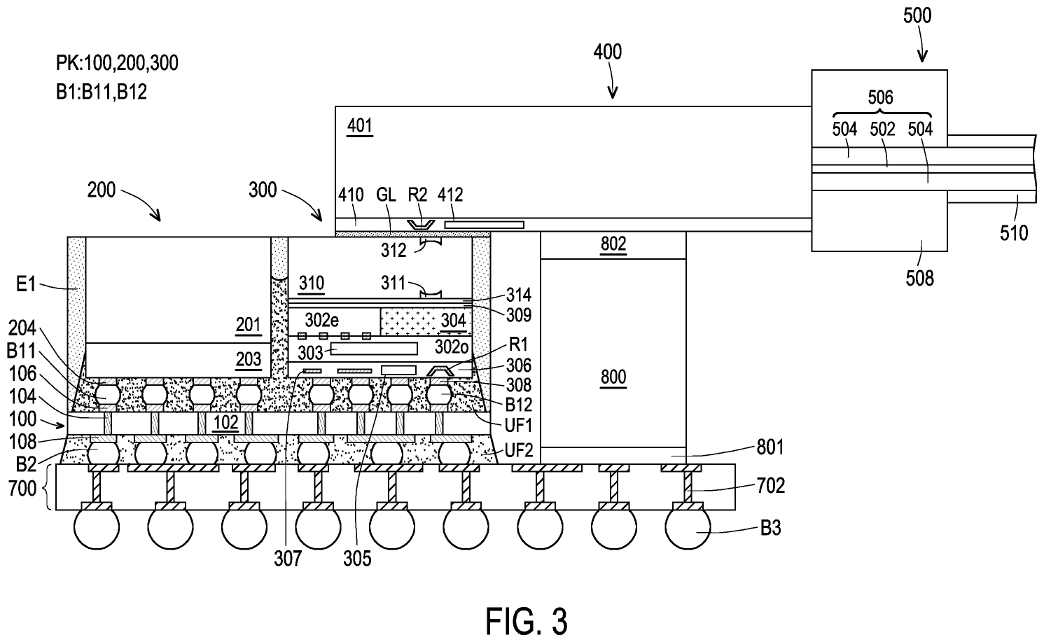

Referring to FIG. 3, the glass substrate 400 with the fiber array unit 500 is bonded to the photonic structure 300. Specifically, the reflector R2 of the glass substrate 400 faces the underlying optical lens 312 of the photonic structure 300, and an optical glue GL is dispensed into the space between the glass substrate 400 and the photonic structure 300 followed by a curing process. The optical glue GL includes a curable adhesive material and has high light transmittance and high adhesion. The optical glue GL may have a convex surface and extend out from the sidewall of the glass base 401. In some embodiments, the dielectric layer 410 of the glass substrate 400 is in physical contact with the optical glue GL and against the buffer layer 802 over the support structure 800.

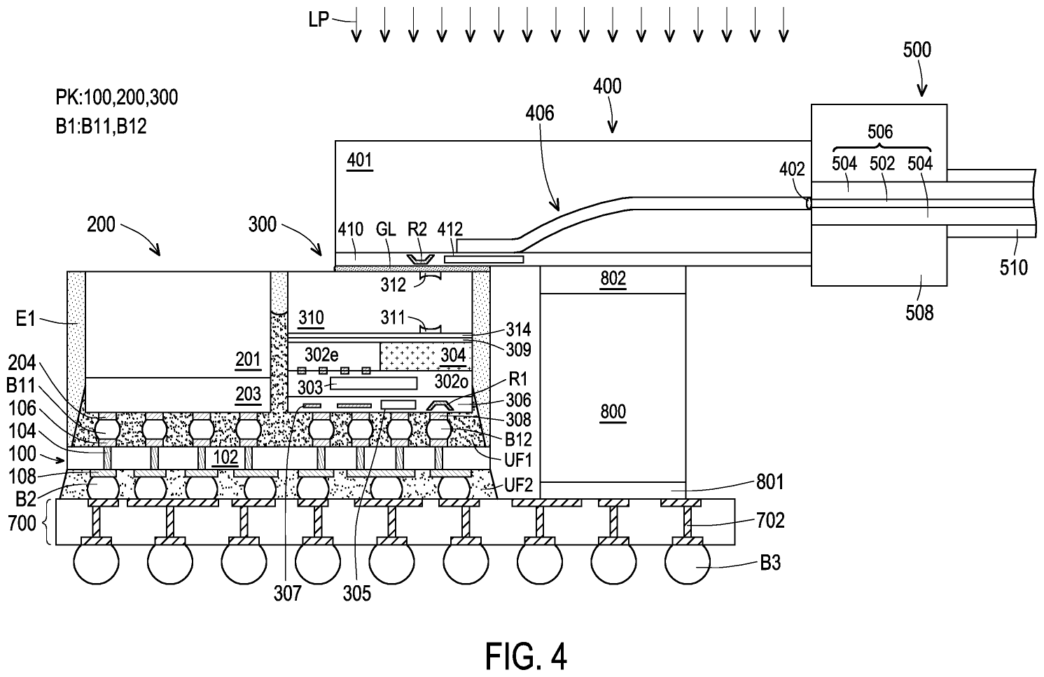

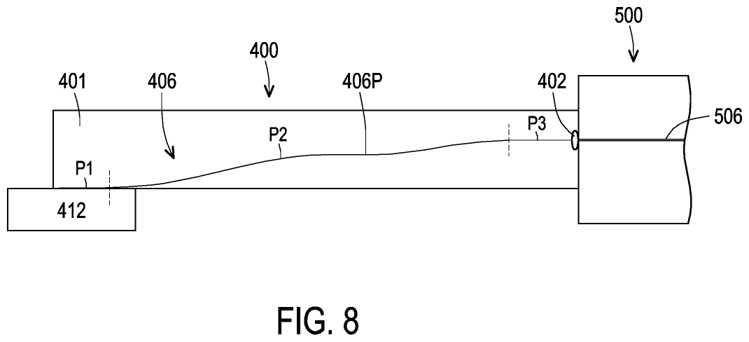

Referring to FIG. 4 and FIG. 7, a laser writing process LP is performed to the glass substrate 400, so as to form a laser written waveguide structure 406 inside the glass substrate 400. The laser writing process LP may be referred to as a three-dimensional (3D) laser writing process in some examples. In some embodiments, the laser writing process LP is performed by a laser writing module including at least one laser source and multiple mirrors. In some embodiments, when a program is input to the laser writing module by an engineer using a computer, the locations of the multiple mirrors may be adjusted to the appropriate locations according to the program. At least one laser beam emitted from the laser source is reflected by the adjusted mirrors and therefore written into the glass substrate to form the desired waveguide path. Specifically, the X-position and Y-position of the waveguide path may be controlled by the adjusted mirrors. At the same time, the stage configured to support the glass substrate may be adjusted vertically, so as to adjust the Z-position of the waveguide path. In some embodiments, multiple waveguide paths are written into the glass substrate sequentially, but the disclosure is not limited thereto. In other embodiments, multiple waveguide paths are written into the glass substrate simultaneously. In some embodiments, the laser writing process LP further forms at least one laser lens 402 between the fiber array unit 500 and the laser written waveguide structure 406. The laser lens 402 is configured to condense a light beam in a desired cross section, or focus a light beam in the desired direction. Specifically, multiple laser lenses 402 are disposed between and in contact with multiple waveguide paths 406P and multiple optical fibers 506, respectively, as shown in FIG. 7. The multiple laser lenses 402 may be omitted in some examples, and multiple waveguide paths 406P are in contact with multiple optical fibers 506, respectively. Since the waveguide structure 406 of the disclosure is formed by a laser writing process, the waveguide paths 406P are written to have curved paths, so as to better match the optical fiber 506 and the optical coupler 412 at two ends of each waveguide path 406P. Specifically, as shown in the cross-sectional view of FIG. 8, each curve waveguide path 406P has two horizontal sub-paths P1 and P3 for better matching the corresponding optical evanescent coupler (EVC) 412 and the optical fiber 506, and a curved and smooth middle sub-path P2 connecting the two horizontal sub-paths P1 and P3. The connecting point between each horizontal sub-path and the middle sub-path is rounded. The horizontal sub-path P1 is overlapped with the optical evanescent coupler (EVC) 412 for better optical coupling. As shown in FIG. 7, the multiple laser written waveguide paths 406P correspond to the multiple laser lenses 402 and therefore the multiple optical fibers 506, respectively.

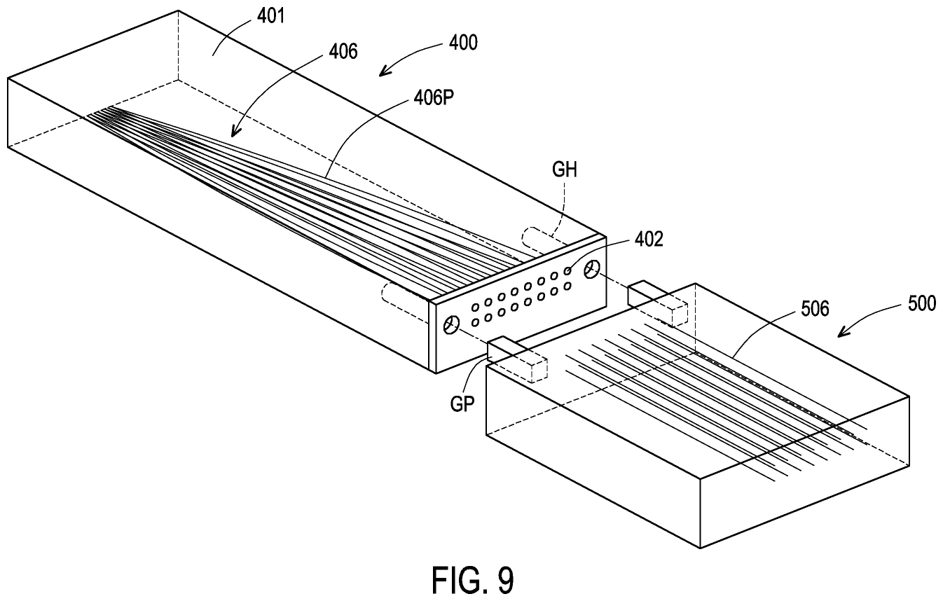

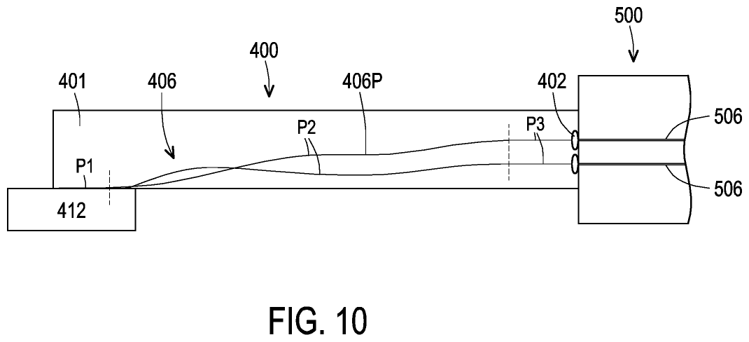

In the embodiments of FIG. 7, one row of laser lenses 402, one row of waveguide paths 406P, and one row of optical fibers 506 are provided for illustration. FIG. 8 illustrates a schematic cross-sectional view of FIG. 7. However, the disclosure is not limited thereto. In some embodiments, two or more rows of laser lenses 402, two or more rows of waveguide paths 406P, and two or more rows of optical fibers 506 can be designed as needed, as shown in FIG. 9. FIG. 10 illustrates a schematic cross-sectional view of FIG. 9.

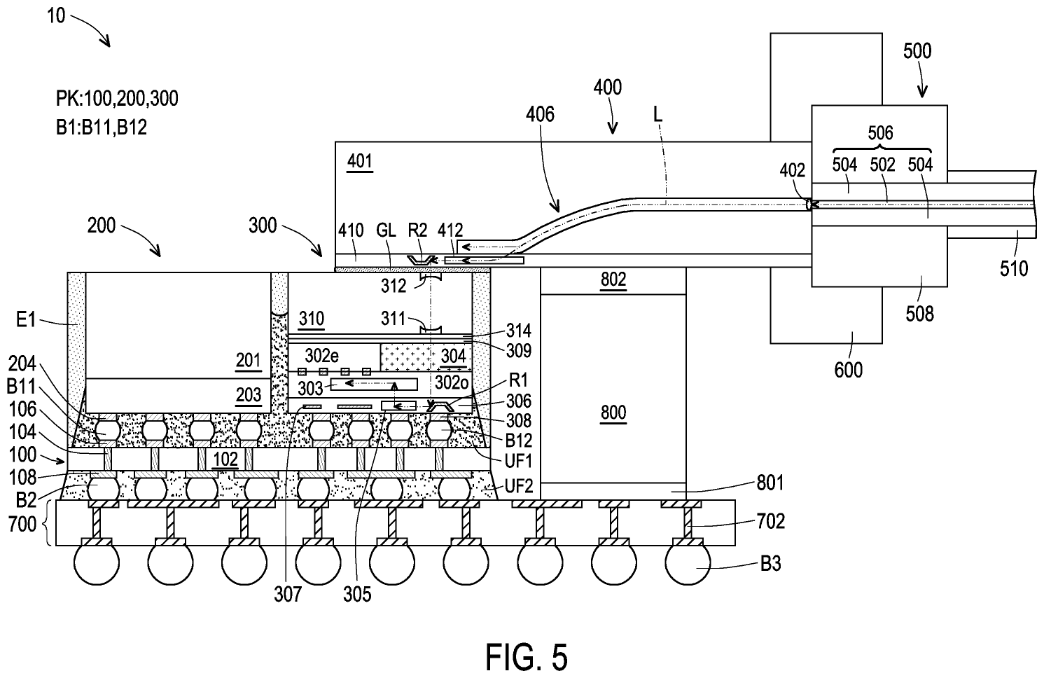

Referring to FIG. 5, after the laser writing process LP, an adaptor case 600 is provided to fix the glass substrate 400 and the FAU 500 together. A package assembly 10 of the disclosure is thus completed. In some embodiments, a lid may be provided over the glass substrate 400 for protecting the underlying components and stiffing the entire package assembly 10, and an optical glue is dispensed into the space between the lid and the glass substrate 400 followed by a curing process. The lid may be a heat dissipation lid or a glass lid.

In some embodiments, as shown in FIG. 5, a light beam L propagates through an optical fiber 506, travels through a laser lens 402 and a laser written waveguide structure 406, and is optically coupled to an optical coupler 412, redirected by the reflector R2, and then optically coupled to a PIC 303 sequentially through an optical lens 312, an optical lens 311, a reflector R1, and an edge coupler and silicon nitride waveguide of the optical component 305.

In the above embodiments, a laser writing process is performed to form a waveguide structure after a glass substrate is bonded to the top surface of a photonic die. However, the disclosure is not limited thereto. In other embodiments, a laser writing process may be performed to a glass substrate to form a waveguide structure, and the glass substrate written with the waveguide structure is then bonded to a photonic structure. In such case, the glass substrate written with the waveguide structure is adjusted to an appropriate location before bonding the glass substrate to the photonic structure. In such case, after the bonding process, an optical glue is dispensed between the glass substrate and the photonic structure, and a buffer layer is then provided between a support structure and the glass substrate to stabilize the glass substrate and therefore the entire package assembly.

With the three-dimensional (3D) laser written waveguide structure of the disclosure, the misalignment issue between a fiber array unit (FAU) and an optical evanescent coupler (EVC) of a photonic structure can be easily resolved, and the coupling tolerance between the FAU and the optical coupler can be greatly improved. Specifically, when the misalignment between the fiber array unit (FAU) and the optical evanescent coupler (EVC) occurs, the waveguide paths of the waveguide structure of the disclosure can be written in appropriate locations by a laser writing process, so as to better match the optical fiber and the optical evanescent coupler (EVC) at two ends of each waveguide path and therefore resolve the misalignment issue.

In the above embodiments, a glass substrate with a laser written waveguide is vertically stacked on top of a photonic structure. However, the disclosure is not limited thereto. In other embodiments, a glass substrate with a laser written waveguide can be disposed laterally aside a photonic structure as needed.

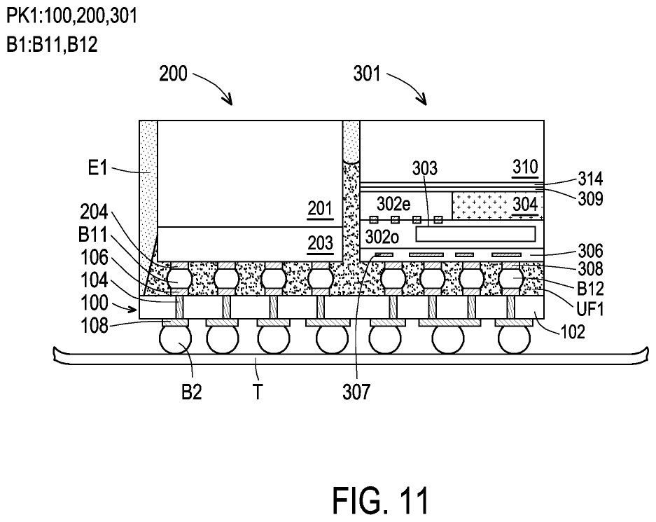

FIG. 11 to FIG. 16 are schematic cross-sectional views of a method of forming a package assembly in accordance with some embodiments. It is understood that the disclosure is not limited by the method described below. Additional operations can be provided before, during, and/or after the method and some of the operations described below can be replaced or eliminated, for additional embodiments of the methods. Although FIG. 11 to FIG. 16 are described in relation to a method, it is appreciated that the structures disclosed in FIG. 11 to FIG. 16 are not limited to such a method, but instead may stand alone as structures independent of the method.

Through the specification, the same or similar reference numerals and/or letters may be used to refer to the same or similar element in the various examples of the disclosure, so the materials, configurations and/or forming methods of elements in FIG. 11 to FIG. 16 may refer to those described in above embodiments.

Referring to FIG. 11, at least one semiconductor package PK1 is attached to a wafer tape T. In some embodiments, the semiconductor package PK1 includes an interposer structure 100, an integrated circuit structure 200 and a photonic structure 301 bonded to the interposer structure 100.

In some embodiments, the integrated circuit structure 200 may include a system device, and the photonic structure 301 may include a photonic device, which will be described in details below. However, the disclosure is not limited thereto. In other embodiments, the semiconductor package PK1 further includes an additional integrated circuit structure bonded to the interposer structure 100 and aside the integrated circuit structure 200. The additional integrated circuit structure may include a memory device such as a dynamic random-access memory (DRAM), a synchronous dynamic random-access memory (SDRAM), a die stack such as a high bandwidth memory (HBM) cube, or the like.

In some embodiments, the interposer structure 100 includes a substrate 102, and through substrate vias 104 penetrating through the substrate 102. In some embodiments, the interposer structure 100 further includes metal pads 104 and metal pads 108 at opposite sides and configured to electrically connected to the overlying and underlying electrical components, semiconductor devices or integrated circuit structures, respectively. In some embodiments, bumps B1 and bumps B2 are further formed on and electrically connected to the metal pads 104 and the metal pads 108, respectively. The bumps B1 may be divided into bumps B11 and bumps B12 for different overlying electrical structures. The size of the bumps B2 may be different from (e.g., greater than) the size of the bumps B1. In some embodiments, the interposer structure 100 is an active interposer. In other embodiments, the interposer structure 100 is a passive interposer.

As shown in FIG. 11, an integrated circuit structure 200 is bonded to the interposer structure 100. In some embodiments, the integrated circuit structure 200 (e.g., system device) includes a substrate 201 and a device layer 203. The device layer 203 may further include an interconnect structure electrically connected to the transistor. In some embodiments, the integrated circuit structure 200 (e.g., system device) is bonded to the interposer structure 100 through the metal pads 204, bumps B11 and the metal pads 104. The bumps B11 may be formed over the metal pads 204, the metal pads 104 or both.

Still referring to FIG. 11, a photonic structure 301 is bonded to the interposer structure 100. In some embodiments, the photonic structure 301 includes, from bottom to top, a photonic die 3020, an electric die 302e and a support die 310. The photonic structure 301 may be referred to as a silicon photonic (SiPh) structure in some examples.

In some embodiments, the photonic die 3020 includes a photonic integrated circuit (PIC) 303. The PIC 303 includes an optical waveguide (such as silicon (Si) waveguide), a modulator, a detector, a grating coupler, an edge coupler, a filter, other optical components, or a combination thereof. In some embodiments, the photonic die 3020 further includes conducive features 307 embedded in at least one dielectric layer 306. The conducive features 307 of the photonic structure 301 are electrically connected to the underlying interposer structure 100.

In some embodiments, the method of forming the photonic die 3020 may include: providing a silicon-on-insulator (SOI) substrate, forming a PIC 303 on/in the active side (e.g., front side) of a silicon layer of the SOI substrate, removing an oxide layer and a semiconductor layer of the SOI substrate, and forming conducive features 307 embedded in at least one dielectric layer 306 on the non-active side (e.g., backside) of the silicon layer.

In some embodiments, the electric die 302e includes an electric integrated circuit (EIC). The PIC of the photonic die 3020 is integrated with the EIC of the electric die 302e, so as to achieve a higher communication performance and a more compact packaging. In some embodiments, the electric die 302e is bonded to the photonic die 3020 through a hybrid bonding including a dielectric-to-dielectric bonding and a metal-to-metal bonding.

In some embodiments, the dimension (e.g., width) of the electric die 302e is less than the dimension (e.g., width) of the photonic die 3020, and an insulating material 304 is provided aside the electric die 302e to fill the space and robust the structure.

In some embodiments, the support die 310 is a semiconductor die, such as a silicon die. In some embodiments, the support die 310 is bonded to the electric die 302e through a dielectric bonding layer 314 and a dielectric bonding layer 309.

In some embodiments, the photonic structure 301 (e.g., photonic device) is bonded to the interposer structure 100 through the metal pads 308, bumps B12 and the metal pads 104. The bumps B12 may be formed over the metal pads 308, the metal pads 104 or both.

Still referring to FIG. 11, after the integrated circuit structure 200 and the photonic structure 301 are bonded to the interposer structure 100, an underfill layer UF1 is formed to fill the space between the interposer structure 100 and each of the integrated circuit structure 200 and the photonic structure 301, and surrounds the bumps B1 including bumps B11 and B12.

Thereafter, an encapsulation layer E1 is formed over the interposer structure 100 and laterally surrounds the integrated circuit structure 200 and the photonic structure 301.

In some embodiments, a wafer dicing process is performed, so as to separate adjacent semiconductor packages PK1 from each other. Each semiconductor package PK1 may have substantially straight sidewalls. In some embodiments, the semiconductor package PK1 includes an interposer structure 100, an integrated circuit structure 200 and an photonic structure 301 bonded to the interposer structure 100, and an encapsulation layer E1 laterally encapsulates sidewalls of the integrated circuit structure 200 while exposes a sidewall of the photonic structure 301. In some embodiments, the exposed sidewall of the photonic structure 301 is flushed with the sidewall of the underlying underfill layer UF1 and the sidewall of the interposer structure 100. The exposed sidewall of the photonic structure 301 is for optically coupling to the subsequently formed laser written waveguide structure, which will be described in details below.

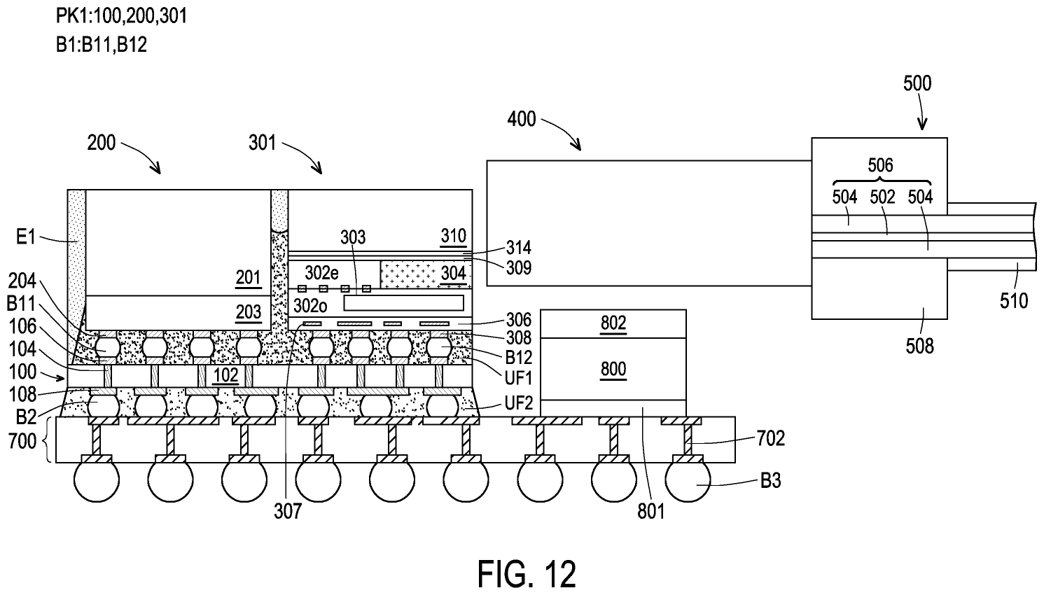

Referring to FIG. 11 and FIG. 12, the wafer tape T is removed, and a board substrate 700 is formed below and electrically connected to the interposer structure 100. In some embodiments, the board substrate 700 is bonded to the interposer structure 100 through the bumps B2.

In some embodiments, the board substrate 700 includes a core layer and two build-up layers on opposite sides of the core layer. In some embodiments, the board substrate 700 includes wiring patterns 702 that penetrate through the core layer and the build-up layers for providing electrical routing between different devices and electric components. The board substrate 700 is referred to as a “printed circuit board (PCB)” in some examples. In other embodiments, the core layer of the board substrate 700 may be omitted as needed, and such board substrate 700 is referred to as a “coreless board substrate”.

Thereafter, an underfill layer UF2 is formed to fill the space between the interposer structure 100 and the board substrate 700, and surrounds the bumps B2.

In some embodiments, a support structure 800 is provided and bonded to the board substrate 700 aside the photonic structure 301 of the semiconductor package PK1. The support structure 800 is configured to support the overlying glass substrate and therefore robust the final structure. In some embodiments, the support structure 800 is a wall structure at a single side of the photonic structure 301, or a ring structure surrounding the photonic structure 301. In such case, the support structure 800 include a heat dissipation material, such as metal. The support structure 800 is attached to the board substrate 700 through an adhesive layer 801. In some embodiments, the support structure 800 has a buffer layer 802 on top thereof. The buffer layer 802 may be an adhesive layer or a thermal interface material (TIM). However, the disclosure is not limited thereto. In other embodiments, the support structure 800 may be a silicon dummy die for eliminating the coefficient thermal expansion (CTE) mismatch and therefore reducing the package warpage issue.

Afterwards, bumps B3 are formed below and electrically connected to the board substrate 700. In some embodiments, bump B3 are electrically to the wiring patterns 702 of the board substrate 700. The size of the bumps B3 may be different from (e.g., greater than) the size of the bumps B2.

Referring to FIG. 12 and FIG. 6, a glass substrate 400 is assembled to a fiber array unit (FAU) 500. In some embodiments, as shown in FIG. 6, the glass substrate 400 has two guide holes GH, the FAU 500 has two guide pins GH, and the glass substrate 400 is assembled to the FAU 500 with the guide pins GH aligning with and embedded to the guide holes GH. The glass substrate 400 is free of laser written patterns at this stage.

Still referring to FIG. 12 and FIG. 6, the FAU 500 includes optical fibers 506 arranged in an array. In some embodiments, each optical fiber 506 includes a glass core 502 and a glass cladding 504 surrounding the glass core 502. In some embodiments, portions of the optical fibers 506 are embedded in a ferrule 508, and the remaining portions of the optical fibers 506 are embedded in a fiber ribbon 510.

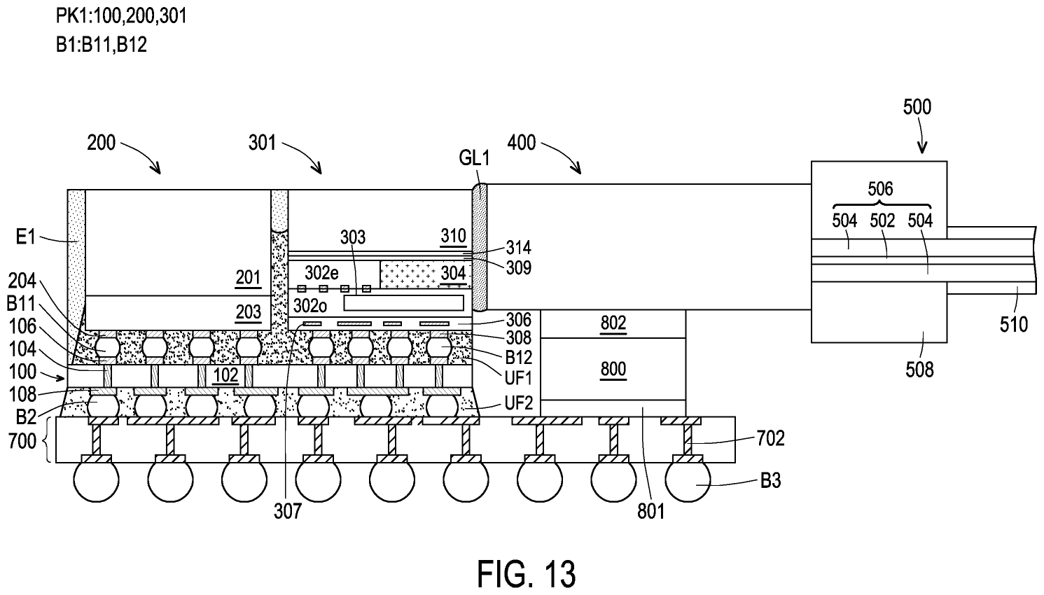

Referring to FIG. 13, the glass substrate 400 with the fiber array unit 500 is bonded to the photonic structure 301. Specifically, the glass substrate 400 faces the exposed sidewall of the photonic structure 301, and an optical glue GL1 is dispensed into the space between the glass substrate 400 and the photonic structure 301 followed by a curing process. The optical glue GL1 includes a curable adhesive material and has high light transmittance and high adhesion. The optical glue GL1 may have a convex surface and extend out from the sidewall of the glass substrate 400. In some embodiments, the glass substrate 400 is against the buffer layer 802 over the support structure 800.

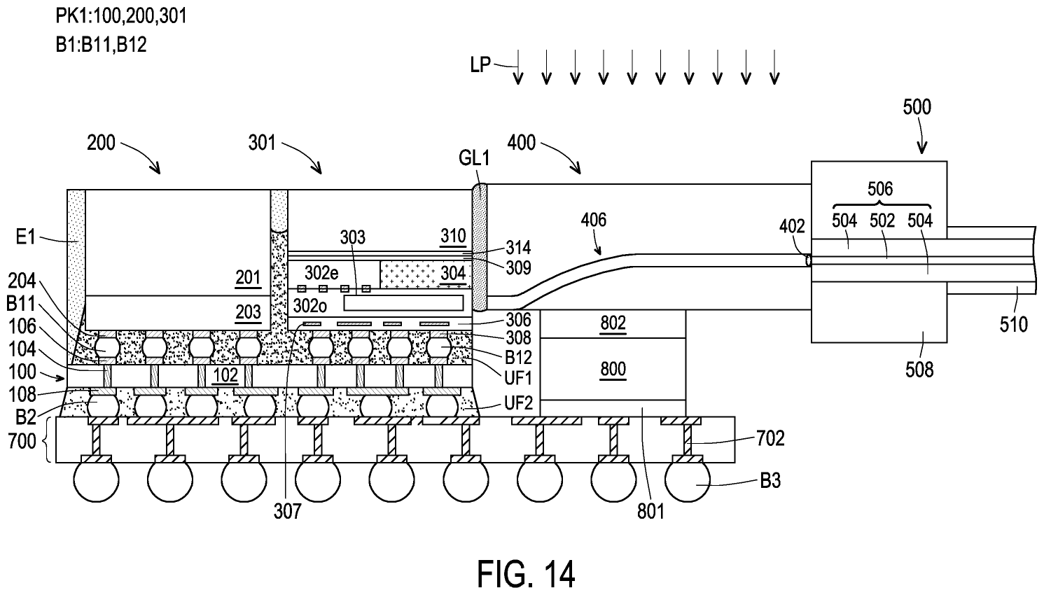

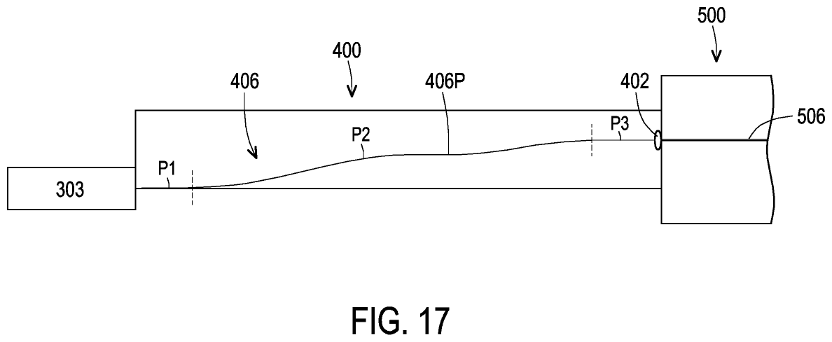

Referring to FIG. 14 and FIG. 7, a laser writing process LP is performed to the glass substrate 400, so as to form a laser written waveguide structure 406 inside the glass substrate 400. The laser writing process LP may be referred to as a three-dimensional (3D) laser writing process in some examples. In some embodiments, the laser writing process LP further forms at least one laser lens 402 between the fiber array unit 500 and the laser written waveguide structure 406. The laser lens 402 is configured to condense a light beam in a desired cross section, or focus a light beam in the desired direction. Specifically, multiple laser lenses 402 are disposed between and in contact with multiple waveguide paths 406P and multiple optical fibers 506, respectively, as shown in FIG. 7. The multiple laser lenses 402 may be omitted in some examples, and multiple waveguide paths 406P are in contact with multiple optical fibers 506, respectively. Since the waveguide structure 406 of the disclosure is formed by a laser writing process, the waveguide paths 406P are written to have curved paths, so as to better match the optical fiber 506 and the edge coupler (EC) of the PIC 303 at two ends of each waveguide path 406P. Specifically, as shown in cross-sectional view of FIG. 17, each curve waveguide path 406P has two horizontal sub-paths P1 and P3 for better matching the edge coupler (EC) of the PIC 303 and the corresponding optical fiber 506, and a curved and smooth middle sub-path P2 connecting the two horizontal sub-paths P1 and P3. The connecting point between each horizontal sub-path and the middle sub-path is rounded. The horizontal sub-path is laterally aligned with the edge coupler of the PIC 303 for better optical coupling. As shown in FIG. 7, the multiple laser written waveguide paths 406P correspond to the multiple laser lenses 402 and therefore the multiple optical fibers 506, respectively.

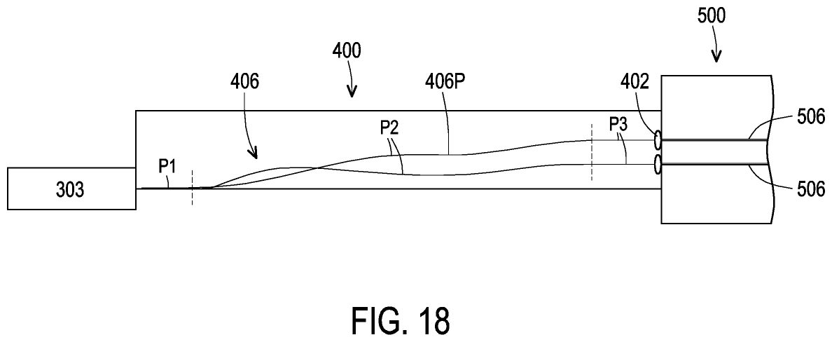

In the embodiments of FIG. 7, one row of laser lenses 402, one row of waveguide paths 406P, and one row of optical fibers 506 are provided for illustration. FIG. 17 illustrates a schematic cross-sectional view of FIG. 7. However, the disclosure is not limited thereto. In some embodiments, two or more rows of laser lenses 402, two or more rows of waveguide paths 406P, and two or more rows of optical fibers 506 can be designed as needed, as shown in FIG. 9. FIG. 18 illustrates a schematic local cross-sectional view of FIG. 9. In some embodiments, as shown in FIG. 18, from a cross-sectional view, the waveguide paths 406P have different profiles.

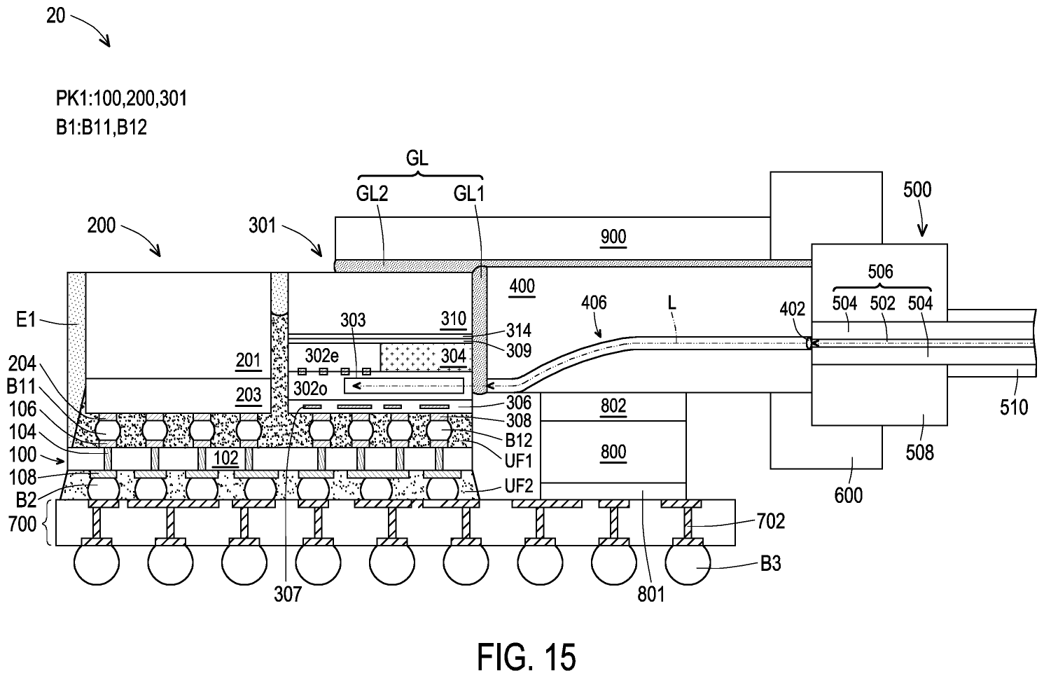

Referring to FIG. 15, after the laser writing process LP, an adaptor case 600 is provided to fix the glass substrate 400 and the FAU 500 together. In some embodiments, a lid 900 may be provided over the glass substrate 400 and the photonic structure 301 for protecting and fixing the underlying glass substrate 400 and the photonic structure 301 together, and an optical glue GL2 is dispensed into the space between the lid 900 and each of the glass substrate 400 and the photonic structure 301 followed by a curing process. The lid 900 may be a heat dissipation lid or a glass lid. The optical glue GL2 includes a curable adhesive material and has high light transmittance and high adhesion. The optical glue GL2 may have a convex surface and extend out from the sidewall of the lid 900. The optical glue GL1 and the optical glue GL2 are collectively referred to as an optical glue GL. In some embodiments, the optical glue GL2 and the optical glue GL1 may include the same material, so an interface is not present between the optical glue GL2 and the optical glue GL1. In other embodiments, the optical glue GL2 and the optical glue GL1 may include different materials, so an interface is present between the optical glue GL2 and the optical glue GL1. A package assembly 20 of the disclosure is thus completed.

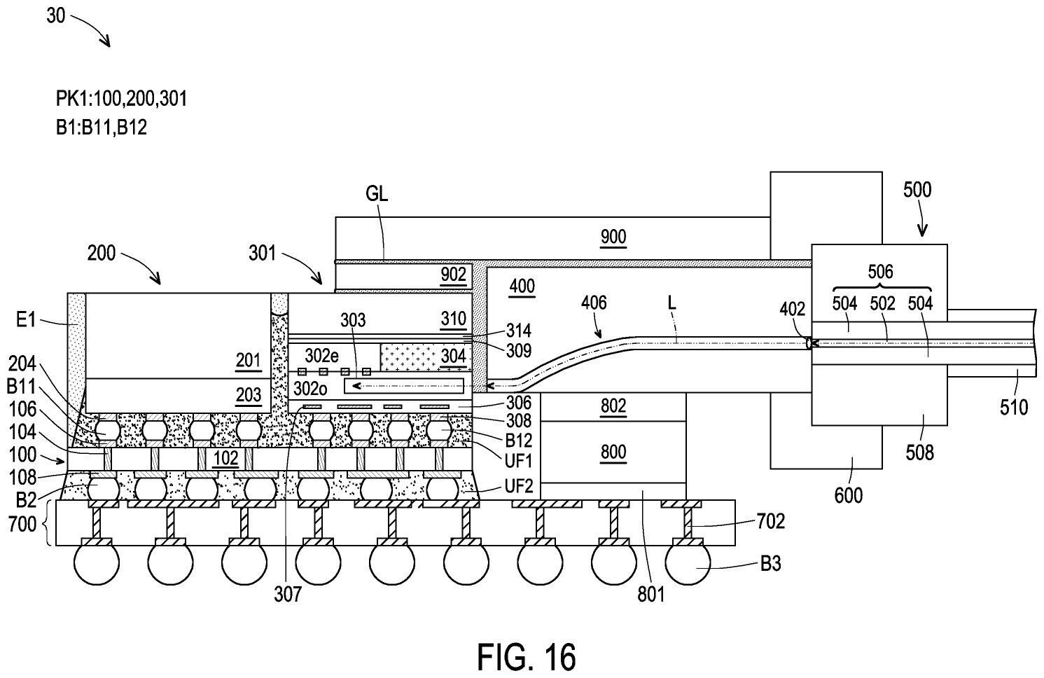

The package assembly 30 of FIG. 16 is similar to the package assembly 20 of FIG. 15, and the different between them lies in that, the package assembly 30 further includes a spacer 902 interposed between the lid 900 and the photonic structure 301, and an optical glue GL is dispensed into the space between the spacer 902 and each of the lid 900, the glass substrate 400, and the photonic structure 301. The spacer 902 may be a heat dissipation spacer or a glass spacer.

In some embodiments, as shown in FIGS. 15 and 16, a light beam L propagates through an optical fiber 506, travels through a laser lens 402 and a laser written waveguide structure 406, and is optically coupled to an edge coupler (EC) of a PIC 303.

In the above embodiments, a laser writing process is performed to form a waveguide structure after a glass substrate is bonded to the sidewall of a photonic die. However, the disclosure is not limited thereto. In other embodiments, a laser writing process may be performed to a glass substrate to form a waveguide structure, and the glass substrate written with the waveguide structure is then bonded to a photonic structure. In such case, the glass substrate written with the waveguide structure is adjusted to an appropriate location before bonding the glass substrate to the photonic structure. In such case, after the bonding process, an optical glue is dispensed between the glass substrate and the photonic structure, and a buffer layer is then provided between a support structure and the glass substrate to stabilize the glass substrate and therefore the entire package assembly.

With the three-dimensional (3D) laser written waveguide structure of the disclosure, the misalignment issue between a fiber array unit (FAU) and an edge coupler of a photonic structure can be easily resolved, and the coupling tolerance between the FAU and the edge coupler can be greatly improved. Specifically, when the misalignment between the fiber array unit (FAU) and the edge coupler occurs, the waveguide paths of the waveguide structure of the disclosure can be written in appropriate locations by a laser writing process, so as to better match the optical fiber and the edge coupler at two ends of each waveguide path and therefore resolve the misalignment issue.

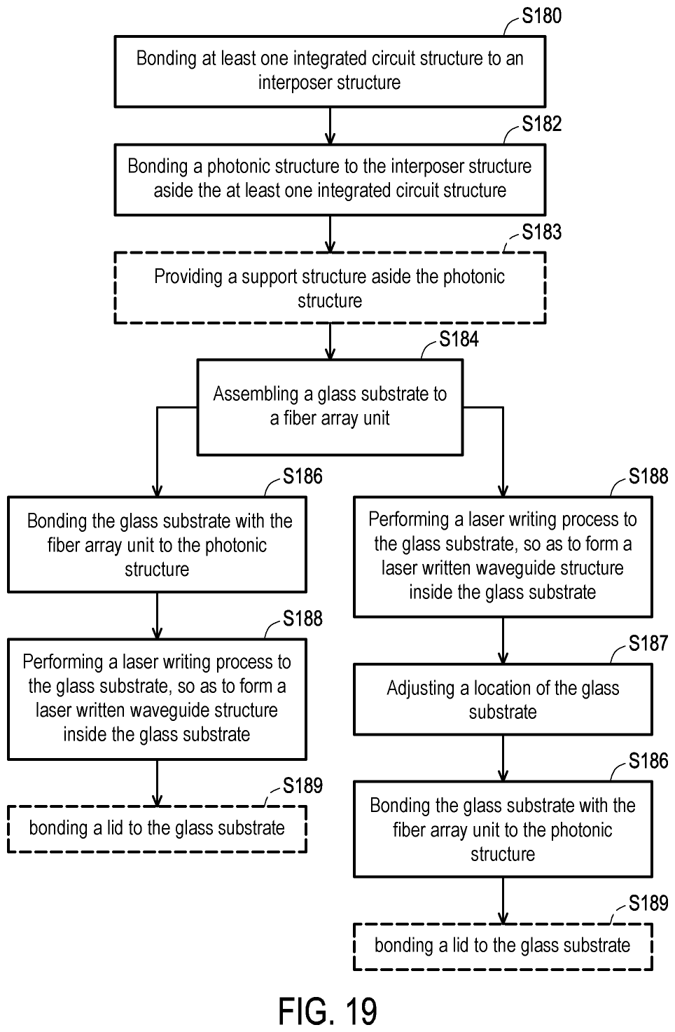

FIG. 19 illustrates a method of forming a package assembly in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S180, at least one integrated circuit structure is bonded to an interposer structure. FIG. 1 and FIG. 11 illustrate cross-sectional views corresponding to some embodiments of act S180.

At act S182, a photonic structure is bonded to the interposer structure aside the at least one integrated circuit structure. FIG. 1 to FIG. 2 and FIG. 11 to FIG. 12 illustrate cross-sectional views corresponding to some embodiments of act S182. In some embodiments, an optical coupler (e.g., evanescent coupler) is formed between the photonic structure and the glass substrate, a first reflector is formed adjacent an optical integrated circuit in the photonic structure, and a second reflector is formed between the photonic structure and the glass substrate and adjacent to the optical coupler, wherein the second reflector and the first reflector are configured to reflect and redirect a light beam received from the optical coupler to the optical integrated circuit, as shown in FIG. 2. In other embodiments, an optical coupler (e.g., edge coupler) is formed inside an optical integrated circuit, as shown in FIG. 12.

At act S183, a support structure is provided aside the photonic structure. FIG. 2 and FIG. 12 illustrate cross-sectional views corresponding to some embodiments of act S183. Act S183 may be optional and may be omitted in some examples.

At act S184, a glass substrate is bonded to a fiber array unit. FIG. 2, FIG. 6 and FIG. 12 illustrate cross-sectional and perspective views corresponding to some embodiments of act S184.

At act S186, the glass substrate with the fiber array unit is bonded to the photonic structure. FIG. 3 and FIG. 13 illustrate cross-sectional views corresponding to some embodiments of act S186.

At act S188, a laser writing process is performed to the glass substrate, so as to form a laser written waveguide structure inside the glass substrate. FIG. 4, FIG. 7 to FIG. 10, and FIG. 14 illustrate cross-sectional views and perspective views corresponding to some embodiments of act S188. The laser written waveguide structure is optically coupled to the fiber array unit and the photonic structure. In some embodiments, the laser writing process further forms at least one laser lens between the fiber array unit and the laser written waveguide structure, as shown in FIG. 4, FIG. 7 to FIG. 10, and FIG. 14. In some embodiments, the laser written waveguide structure has a plurality of curved waveguide paths, as shown in FIG. 8 and FIG. 10.

At act S189, a lid is bonded to the glass substrate. FIG. 15 and FIG. 16 illustrate cross-sectional views corresponding to some embodiments of act S189. In some embodiments, the lid is bonded to the photonic structure and the glass substrate, as shown in FIG. 15 and FIG. 16. In some embodiments, a spacer is further formed between the lid and the photonic structure, as shown in FIG. 16. Act S189 may be optional and may be omitted in some examples, as shown in FIG. 5.

In the above forming sequence, bonding the glass substrate to the photonic structure (act S186) is performed before performing the laser writing process (act S188). However, the disclosure is not limited thereto. In other embodiments, bonding the glass substrate to the photonic structure (act S186) is performed after performing the laser writing process (act S188). In such case, act S187 of adjusting a location of the glass substrate may be implemented between act S188 and act S186.

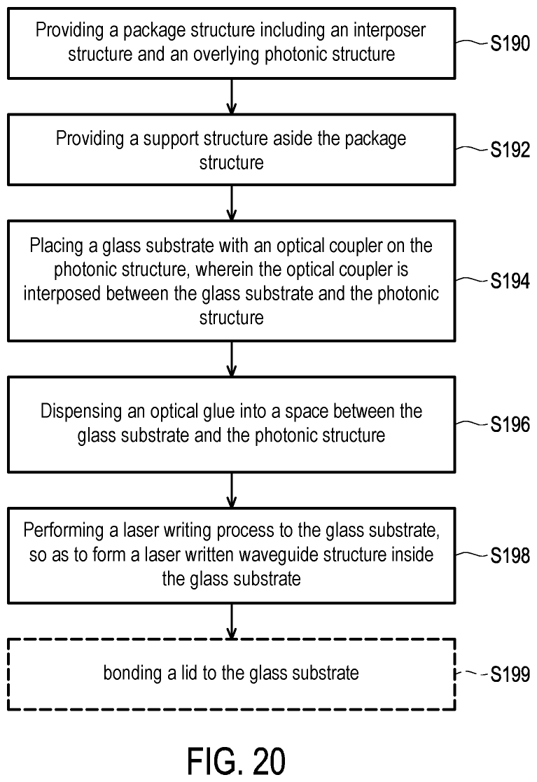

FIG. 20 illustrates a method of forming a package assembly in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S190, a package structure is provided, and the package structure includes an interposer structure and an overlying photonic structure. FIG. 1 illustrates a cross-sectional view corresponding to some embodiments of act S190.

At act S192, a support structure is provided aside the package structure. FIG. 2 illustrates a cross-sectional view corresponding to some embodiments of act S192.

At act S194, a glass substrate with an optical coupler is placed on the photonic structure, wherein the optical coupler is interposed between the glass substrate and the photonic structure. FIG. 3 illustrates a cross-sectional view corresponding to some embodiments of act S194.

At act S196, an optical glue is dispensed into a space between the glass substrate and the photonic structure. FIG. 3 illustrates a cross-sectional view corresponding to some embodiments of act S196. In some embodiments, a buffer layer is provided between the support structure and the glass substrate before act S196. In other embodiments, a buffer layer is provided between the support structure and the glass substrate after act S196.

At act S198, a laser writing process is performed to the glass substrate, so as to form a laser written waveguide structure inside the glass substrate. FIG. 4 and FIG. 7 to FIG. 10 illustrate cross-sectional views and perspective views corresponding to some embodiments of act S198. In some embodiments, the laser writing process further forms at least one laser lens between a fiber array unit and the laser written waveguide structure, wherein the laser written waveguide structure has a plurality of curved waveguide paths.

At act S199, a lid is bonded to the glass substrate. Act S199 may be optional and may be omitted in some examples, as shown in FIG. 5.

The package assemblies of the disclosure are illustrated below with reference to FIG. 5 to FIG. 10 and FIG. 15 to FIG. 18.

In some embodiments, a package assembly Oct. 20, 1930 includes a photonic structure 300/301, an encapsulation layer E1 and a laser written waveguide structure 406. The photonic structure 300/301 is disposed on an interposer structure 100. The encapsulation layer E1 is laterally aside the photonic structure 300/301. The laser written waveguide structure 406 is embedded in a glass substrate 400 and disposed adjacent to the photonic structure 300/301, wherein the laser written waveguide structure 406 has a plurality of curved waveguide paths 406P.

In some embodiments, the package assembly Oct. 20, 1930 further includes a plurality of laser lenses 402 embedded in the glass substrate 400 and in contact with the laser written waveguide structure 406.

In some embodiments, the laser written waveguide structure 406 is bonded to a top surface of the photonic structure 300, as shown in FIG. 5. In some embodiments, the laser written waveguide structure 406 is optically coupled to the PIC 303 through an evanescent coupler (EVC) 412. The evanescent coupler (EVC) 412 is overlapped with the laser written waveguide structure 406 in cross section.

In some embodiments, the laser written waveguide structure 406 is bonded to a sidewall of the photonic structure 301, as shown in FIG. 15 and FIG. 16. In some embodiments, the laser written waveguide structure 406 is optically coupled to the edge coupler of the PIC 303. The edge coupler of the PIC 303 is laterally aligned with the laser written waveguide structure 406.

In view of above, with the three-dimensional (3D) laser written waveguide structure of the disclosure, the misalignment issue between a fiber array unit (FAU) and a photonic structure can be easily resolved, and the coupling tolerance between the FAU and the photonic structure can be greatly improved. With optical interconnection provided by the photonic structure, higher communication performance and more compact packaging can be easily achieved.

Many variations of the above examples are contemplated by the disclosure. It is understood that different embodiments may have different advantages, and that no particular advantage is necessarily required of all embodiments.

In accordance with some embodiments of the disclosure, a package assembly includes the following operations. At least one integrated circuit structure is bonded to an interposer structure. A photonic structure is bonded to the interposer structure aside the at least one integrated circuit structure. A glass substrate is assembled to a fiber array unit. The glass substrate with the fiber array unit is bonded to the photonic structure. A laser writing process is performed to the glass substrate, so as to form a laser written waveguide structure inside the glass substrate, wherein the laser written waveguide structure is optically coupled to the fiber array unit and the photonic structure.

In accordance with some embodiments of the disclosure, a method of forming a package assembly includes following operations. A package structure is provided. The package structure includes an interposer structure and an overlying photonic structure. A glass substrate with an optical coupler is placed on the photonic structure, wherein the optical coupler is interposed between the glass substrate and the photonic structure. A laser writing process is performed to the glass substrate, so as to form a laser written waveguide structure inside the glass substrate.

In accordance with some embodiments of the disclosure, a package assembly includes a photonic structure, an encapsulation layer and a laser written waveguide structure. The photonic structure is disposed on an interposer structure. The encapsulation layer is laterally aside the photonic structure. The laser written waveguide structure is embedded in a glass substrate and disposed adjacent to the photonic structure, wherein the laser written waveguide structure has a plurality of curved waveguide paths.

In accordance with some embodiments of the disclosure, a package assembly includes a photonic structure, a laser written waveguide structure and a fiber array unit. The photonic structure disposed on an interposer structure. The laser written waveguide structure is embedded in a glass substrate and disposed adjacent to the photonic structure, wherein the laser written waveguide structure has a plurality of waveguide paths. The fiber array unit is disposed laterally adjacent to the laser written waveguide structure, wherein the fiber array unit includes a plurality of optical fibers corresponding to the plurality of the waveguide paths. In some embodiments, from a cross-sectional view, the plurality of waveguide paths have different profiles.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A method of forming a package assembly, comprising:
bonding at least one integrated circuit structure to an interposer structure;
bonding a photonic structure to the interposer structure aside the at least one integrated circuit structure;
assembling a glass substrate to a fiber array unit;
bonding the glass substrate with the fiber array unit to the photonic structure; and
performing a laser writing process to the glass substrate, so as to form a laser written waveguide structure inside the glass substrate, wherein the laser written waveguide structure is optically coupled to the fiber array unit and the photonic structure.

2. The method of claim 1, wherein the laser writing process further forms at least one laser lens between the fiber array unit and the laser written waveguide structure.

3. The method of claim 1, wherein the laser written waveguide structure has a plurality of curved waveguide paths.

4. The method of claim 1, wherein bonding the glass substrate to the photonic structure is performed before performing the laser writing process.

5. The method of claim 1, wherein bonding the glass substrate to the photonic structure is performed after performing the laser writing process.

6. The method of claim 5, further comprising adjusting a location of the glass substrate before bonding the glass substrate to the photonic structure and after performing the laser writing process.

7. The method of claim 1, further comprising forming an evanescent coupler between the photonic structure and the glass substrate.

8. The method of claim 1, further comprising forming an edge coupler inside an optical integrated circuit, and the laser written waveguide structure inside the glass substrate is laterally aligned with the edge coupler.

9. The method of claim 1, further comprising bonding a lid to the photonic structure and the glass substrate.

10. A package assembly, comprising:
a photonic structure disposed on an interposer structure;
an encapsulation layer laterally aside the photonic structure; and
a laser written waveguide structure embedded in a glass substrate and disposed adjacent to the photonic structure, wherein the laser written waveguide structure has a plurality of curved waveguide paths.

11. The package assembly of claim 10, further comprising a plurality of laser lenses embedded in the glass substrate and in contact with the laser written waveguide structure.

12. The package assembly of claim 10, wherein the glass substrate with the laser written waveguide structure is bonded to a top surface of the photonic structure.

13. The package assembly of claim 12, further comprising an evanescent coupler disposed between the photonic structure and the glass substrate.

14. The package assembly of claim 13, further comprising:
a first reflector disposed adjacent an optical integrated circuit in the photonic structure; and
a second reflector disposed between the photonic structure and the glass substrate and adjacent to the evanescent coupler, wherein the second reflector and the first reflector are configured to reflect and redirect a light beam received from the evanescent coupler to the optical integrated circuit.

15. The package assembly of claim 10, wherein glass substrate with the laser written waveguide structure is bonded to a sidewall of the photonic structure.

16. The package assembly of claim 15, further comprising an edge coupler disposed inside an optical integrated circuit of the photonic structure, and the laser written waveguide structure inside the glass substrate is laterally aligned with the edge coupler.

17. The package assembly of claim 15, further comprising bonding a lid to the photonic structure and the glass substrate.

18. A package assembly, comprising:
a photonic structure disposed on an interposer structure;
a laser written waveguide structure embedded in a glass substrate and disposed adjacent to the photonic structure, wherein the laser written waveguide structure has a plurality of waveguide paths; and
a fiber array unit disposed laterally adjacent to the laser written waveguide structure, wherein the fiber array unit comprises a plurality of optical fibers corresponding to the plurality of the waveguide paths,
wherein from a cross-sectional view, the plurality of waveguide paths have different profiles.

19. The package assembly of claim 18, further comprising a plurality of laser lenses embedded in the glass substrate, wherein the laser lenses are disposed between and in contact with the waveguide paths and the optical fibers, respectively.

20. The package assembly of claim 18, further comprising a support structure disposed on the interposer aside the photonic structure and configured to support the glass substrate.
